(19) United States
(12) Patent Application Publication
(10) Pub. No.: US 2022/0322505 A1
(43) Pub. Date: Oct. 6, 2022

(54) THERMAL MATERIAL AND A METHOD OF MAKING THE SAME

(71) Applicant: National University of Singapore, Singapore (SG)

(72) Inventors: Daria Andreeva-Baeumler, Singapore (SG); Konstantin Novoselov, Singapore (SG)

(73) Assignee: National University of Singapore, Singapore (SG)

(21) Appl. No.: 17/709,811

(22) Filed: Mar. 31, 2022

(30) Foreign Application Priority Data
Mar. 31, 2021 (SG) 10202103343W

(51) Int. Cl. H05B 7/06; C23C 16/26

(52) U.S. Cl. CPC H05B 7/06; C23C 16/26

(57) ABSTRACT

There is provided a thermal material comprising an electrode, a film of reduced graphene oxide, a porous membrane that is sandwiched between the electrode and the film of reduced graphene oxide, and an ionic liquid that is disposed within pores of the porous membrane. There is also provided a method of preparing a thermal material. There is further provided a method of changing an article's apparent temperature. There is further provided a device comprising the thermal material as described herein.

### CROSS REFERENCES TO RELATED APPLICATIONS

This application claims priority to Singapore patent application number 10202103343W filed with the Intellectual Property Office of Singapore on 31 Mar. 2021, the contents of which is hereby incorporated by reference in its entirety.

### TECHNICAL FIELD

The present invention generally relates to a thermal material comprising an electrode, a film of reduced graphene oxide, a porous membrane that is sandwiched between the electrode and the film of reduced graphene oxide, and an ionic liquid that is disposed within pores of the porous membrane. The present invention also relates to a method of preparing a thermal material. The present invention further relates to a method of changing an article's apparent temperature. The present invention further relates to a device comprising the thermal material as described herein.

### BACKGROUND ART

Graphene materials are conventionally used for their superior electrical, optical, thermal and mechanical properties. While graphene has been conventionally applied in electronics (such as transistor and transparent electrode), there are limited optical applications of graphene materials.

A conventional optical device of graphene materials requires chemical vapor deposition of a graphene film on a nickel foil to achieve an infrared stealth of the device. Complex steps are needed to fabricate the conventional device and a high cost is needed for graphene and facilities used in the fabrication of the device.

Accordingly, there is a need for a device that addresses or ameliorates the problems described above.

### SUMMARY

In one aspect, there is provided a thermal material comprising:

(a) an electrode;
(b) a film of reduced graphene oxide;
(c) a porous membrane that is sandwiched between the electrode and the film of reduced graphene oxide; and
(d) an ionic liquid that is disposed within pores of the porous membrane.

Advantageously, graphene materials, especially graphene oxide, have a strong interaction with light, which enables a significant absorption (2.3% for one atomic layer) across the infrared and visible range. Graphene materials have a broad optical absorption that can be effectively tuned by electrical gating due to its two-dimensional (2D) structure and dirac-cone band structure: by shifting of the Fermi level (EF), the interband transition with photo energies <I2E_{F}I is forbidden due to Pauli blocking. Thus, graphene materials' optical absorption and emissivity are suppressed. The optical properties of graphene materials as described above make them capable of real-time control thermal radiation, achieving an infrared stealth.

Further advantageously, the porous membrane may serve as a reservoir for the ionic liquid. The ionic liquid comprises cations and anions, which may move in opposite directions to either the electrode or the film of reduced graphene oxide when a bias voltage is applied between the electrode and the film of reduced graphene oxide.

Still further advantageously, the film of reduced graphene oxide is highly flexible. Thus, where the porous membrane and the electrode are flexible, the thermal material may be easily coated onto (or wrapped around) an article to adjust the article's apparent temperature.

In another aspect, there is provided a method of preparing a thermal material, comprising the steps of:

(a) disposing a film of reduced graphene oxide on a first side of a porous membrane;
(b) adding an electrode on a second side of the porous membrane, the second side being opposite to the first side of the porous membrane; and
(c) filling pores of the porous membrane with an ionic liquid.

Advantageously, the reduced graphene oxide may be easily converted from graphene oxide, which can be dissolved in an aqueous medium to form a solution. The solution may then be simply filtered through the porous membrane to obtain a film of graphene oxide, which does not require complex deposition methods.

Further advantageously, the porous membrane may serve as a reservoir for the ionic liquid. The ionic liquid comprises cations and anions, which may move in opposite directions to either the electrode or the film of reduced graphene oxide when a bias voltage is applied between the electrode and the film of reduced graphene oxide of the thermal material prepared from this method.

In another aspect, there is provided a method of changing an article's apparent temperature, comprising the steps of:

(a) coating a surface of the article with a thermal material, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane; and
(b) applying a bias voltage between the electrode of the thermal material and the film of reduced graphene oxide of the thermal material to drive anions of the ionic liquid to the film of reduced graphene oxide.

Advantageously, the bias voltage may be suitably selected to change to change the article's apparent temperature to a desired extent. The bias voltage may have a low threshold (such as 3 V) which can be easily reached.

Further advantageously, the change to the article's apparent temperature is reversible by reversing the bias voltage's direction.

In another aspect, there is provided a device comprising:

(a) an article;
(b) a thermal material coated on a surface of the article, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane; and
(c) a power supply connected to the thermal material.

Advantageously, the device may have a tuneable apparent temperature when a bias voltage is applied in the thermal material by the power supply.

### Definitions

The following words and terms used herein shall have the meaning indicated:

The term “flexible” when used in connection with a material defines that the material may have a flexural modulus in the range of about 2500 MPa to about 2900 MPa.

The term “apparent temperature” when used to define an article refers to the article's temperature as calculated from thermal radiation of the article by the Stefan-Boltzmann law.

The term “ionic liquid” as used herein refers to a salt having a melting point that is lower than 20° C.

The word “substantially” does not exclude “completely” e.g., a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

The term “about” as used herein typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### DETAILED DISCLOSURE OF EMBODIMENTS

Exemplary, non-limiting embodiments of a thermal material will now be disclosed.

The thermal material may comprise:

(a) an electrode;
(b) a film of reduced graphene oxide;
(c) a porous membrane that is sandwiched between the electrode and the film of reduced graphene oxide; and
(d) an ionic liquid that is disposed within pores of the porous membrane.

The electrode may be any conductive material. The electrode may comprise gold, copper, silver, titanium, platinum, tungsten or combinations thereof. The electrode may be a layer. The electrode may be a gold mesh. The gold mesh may be prepared by atomic layer deposition.

Advantageously, where the electrode comprises gold, the electrode may serve as an obstruct layer to block transmission of infrared radiations.

Where the electrode is a layer, the thickness of the electrode layer may be in the range of about 10 nm to about 2000 nm, about 100 nm to about 2000 nm, about 1000 nm to about 2000 nm, about 10 nm to about 1000 nm or about 10 nm to about 100 nm.

The film of reduced graphene oxide may comprise a plurality of single-layered reduced graphene oxide. The single-layered reduced graphene oxide may have a thickness of about 0.8 nm. The film of reduced graphene oxide may comprise about 100 layers to about 2500 layers of the single-layered reduced graphene oxide.

Advantageously, the single-layered reduced graphene oxide may react with the ionic liquid more efficiently. The ionic liquid comprises cations and anions. When a bias voltage is applied between the electrode and the film of reduced graphene oxide, ions flowing to the film of reduced graphene oxide may intercalate the single-layered reduced graphene oxide more rapidly than bi-layered or multi-layered reduced graphene oxide. Therefore, the thermal material may have a lower response time and a higher performance than a material using bi-layered or multi-layered reduced graphene oxide.

The film of reduced graphene oxide may have a thickness in the range of about 100 nm to about 2000 nm, about 1000 nm to about 2000 nm or about 100 nm to about 1000 nm.

The film of reduced graphene oxide may be prepared from a film of graphene oxide by reduction in situ.

The porous membrane may comprise organic materials, inorganic materials or a combination thereof. The porous membrane may comprise polymeric materials. The porous membrane may be substantially chemically inert. The porous membrane may comprise polyethersulfone.

The porous membrane may have suitable mechanical properties. As an example, the porous membrane may have a tensile strength in the range of about 80 MPa to about 85 MPa. The porous membrane may additionally or alternatively have an elongation at break in the range of about 25% to about 80%. The porous membrane may additionally or alternatively have an elongation at yield in the range of about 6.5%. The porous membrane may additionally or alternatively have a flexural yield strength in the range of about 120 MPa to about 140 MPa. The porous membrane may additionally or alternatively have a compressive strength in the range of about 100 MPa to about 110 MPa.

The porous membrane may be at least partially microporous, mesoporous or microporous. The porous membrane may have a pore size in the range of about 10 nm to about 1000 nm, about 10 nm to about 100 nm or about 100 nm to about 1000 nm as measured by adsorption techniques or microscopy. The porous membrane may have a pore size of about 30 nm.

The porous membrane may have a thickness of at least about 10 μm. The porous membrane may have a thickness in the range of about 10 μm to about 100 μm, about 50 μm to about 100 μm or about 10 μm to about 50 μm.

As the thickness of the porous membrane is far higher than the thickness of the film of reduced graphene oxide, the porous membrane may be referred to as an asymmetric membrane.

The ionic liquid may have a boiling point that is higher than 200° C. Therefore, the ionic liquid may be referred to as being non-volatile.

The ionic liquid may be an electrolyte. The ionic liquid may be 1-butyl-3-methylimidazolium hexafluorophosphate (BMIMPF₆), 1-butyl-3-methylimidazolium tetrafluoroborate (BMIMBF₄) or a combination thereof.

The electrode and the porous membrane may be flexible. As the film of reduced graphene oxide is already highly flexible, the thermal material may be flexible.

Referring to FIG. 1A, the thermal material may comprise a film of reduced graphene oxide, a porous polyethersulfone membrane and a back gold mesh. The film of reduced graphene oxide may serve as a top electrode while the back gold mesh may serve as a bottom electrode. Therefore, the thermal material may be adapted to be connected to a power supply.

The back gold mesh may also serve as an obstruct layer to block transmission of IR radiation in background. An ionic liquid (such as BMIMPF₆) may then be injected into the thermal material through capillary action.

Exemplary, non-limiting embodiments of a method of preparing a thermal material will now be disclosed.

The method may comprise the steps of:

(a) disposing a film of reduced graphene oxide on a first side of a porous membrane;
(b) adding an electrode on a second side of the porous membrane, the second side being opposite to the first side of the porous membrane; and
(c) filling pores of the porous membrane with an ionic liquid.

The disposing step (a) may comprise:

(a1) filtering a dispersion of graphene oxide through the porous membrane to form a film of graphene oxide on the porous membrane; and
(a2) reducing the film of graphene oxide to form a film of reduced graphene oxide.

In the filtering step (a1), the dispersion of graphene oxide may comprise single-layered graphene oxide. The single-layered graphene oxide may have a thickness of about 0.8 nm.

The dispersion of graphene oxide may have a concentration in the range of about 3 mg/L to about 30 mg/L, about 10 mg/L to about 30 mg/L or about 3 mg/L to about 10 mg/L. The dispersion of graphene oxide may have a concentration of about 10 mg/L.

The dispersion of graphene oxide may have a volume that is suitably selected to form the film of graphene oxide with a thickness in the range of about 100 nm to about 2000 nm, about 1000 nm to about 2000 nm or about 100 nm to about 1000 nm. As an example, the dispersion of graphene oxide may have a volume in the range of about 20 mL to about 100 mL, about 50 mL to about 100 mL or about 20 mL to about 50 mL.

The porous membrane may comprise organic materials, inorganic materials or a combination thereof. The porous membrane may comprise polymeric materials. The porous membrane may be substantially chemically inert. The porous membrane may comprise polyethersulfone.

The porous membrane may have suitable mechanical properties. As an example, the porous membrane may have a tensile strength in the range of about 80 MPa to about 85 MPa. The porous membrane may additionally or alternatively have an elongation at break in the range of about 25% to about 80%. The porous membrane may additionally or alternatively have an elongation at yield in the range of about 6.5%. The porous membrane may additionally or alternatively have a flexural yield strength in the range of about 120 MPa to about 140 MPa. The porous membrane may additionally or alternatively have a compressive strength in the range of about 100 MPa to about 110 MPa.

The porous membrane may be at least partially microporous, mesoporous or microporous. The porous membrane may have a pore size in the range of about 10 nm to about 1000 nm, about 10 nm to about 100 nm or about 100 nm to about 1000 nm as measured by adsorption techniques or microscopy. The porous membrane may have a pore size of about 30 nm.

The porous membrane may have a thickness of at least about 10 μm. The porous membrane may have a thickness in the range of about 10 μm to about 100 μm, about 50 μm to about 100 μm or about 10 μm to about 50 μm.

The filtering step (a1) may be undertaken by gravitational filtration or vacuum filtration.

During the filtering step (a1), graphene oxide may spontaneously form layers as such structures are thermodynamically favoured. Thus, the film of graphene oxide (and the film of reduced graphene oxide formed thereafter) may be referred to as being self-assembled.

In the reducing step (a2), the film of graphene oxide may be reduced by a composition comprising a reductant.

In the composition, the reductant may be ascorbic acid, hydrazine, hydrogen or combinations thereof.

The composition may be an aqueous solution of ascorbic acid. In the aqueous solution, ascorbic acid may have a concentration in the range of about 10 mg/mL to about 50 mg/mL, about 10 mg/mL to about 30 mg/mL or about 30 mg/mL to about 50 mg/mL. The concentration of ascorbic acid in the aqueous solution may be about 30 mg/mL.

The reducing step (a2) may be undertaken by exposing the film of graphene oxide to the composition comprising a reductant for a duration in the range of about 12 hours to about 36 hours, about 12 hours to about 24 hours or about 24 hours to about 36 hours. The reducing step (a2) may be undertaken for a duration of about 24 hours.

The reducing step (a2) may alternatively be undertaken until the film of graphene oxide completely changes its colour. As an example, the film of graphene oxide before the reducing step (a2) may have a light yellow colour. The reducing step (a2) may then be undertaken until the film completely turns to a dark colour.

The disposing step (a) may further comprise a step of drying of the film of reduced graphene oxide.

The drying step may be undertaken overnight. The drying step may alternatively be undertaken for a duration in the range of about 4 hours to about 12 hours, about 8 hours to about 12 hours or about 4 hours to about 8 hours.

The drying step may be undertaken at room temperature.

The drying step may be undertaken in a dry cabinet.

In the adding step (b), the electrode may be a conductive material that is not particularly limited. The electrode may comprise gold, copper, silver, titanium, platinum, tungsten or combinations thereof. The electrode may be a layer. The electrode may be a gold mesh.

Advantageously, where the electrode comprises gold, the electrode may serve as an obstruct layer to block transmission of infrared radiations.

The adding step (b) may be undertaken by atomic layer deposition of gold on the film of reduced graphene oxide.

The adding step (b) may be undertaken until the electrode has a thickness in the range of about 10 nm to about 2000 nm, about 100 nm to about 2000 nm, about 1000 nm to about 2000 nm, about 10 nm to about 1000 nm or about 10 nm to about 100 nm.

The filling step (c) may be undertaken by exposing the porous membrane to the ionic liquid. Therefore, ionic liquid may enter pores of the porous membrane by capillary action.

The filling step (c) may be undertaken for a duration in the range of about 1 hour to about 3 hours, about 2 hours to about 3 hours or about 1 hour to about 2 hours.

In the filling step (c), the ionic liquid may have a boiling point that is higher than 200° C. Therefore, the ionic liquid may be referred to as being non-volatile.

The ionic liquid may be an electrolyte. The ionic liquid may be 1-butyl-3-methylimidazolium hexafluorophosphate (BMIMPF₆), 1-butyl-3-methylimidazolium tetrafluoroborate (BMIMBF₄) or a combination thereof.

Exemplary, non-limiting embodiments of a method of changing an article's apparent temperature will now be disclosed.

The method may comprise the steps of:

(a) coating a surface of the article with a thermal material, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane;
(b) applying a bias voltage between the electrode of the thermal material and the film of reduced graphene oxide of the thermal material to drive anions of the ionic liquid to the film of reduced graphene oxide.

The method may further comprise a step of reversing the bias voltage to drive anions of the ionic liquid to the electrode.

Where the bias voltage is reversed, the change in the article's apparent temperature is reversed as well. Therefore, the change in the article's apparent temperature is reversible and may be suitably increased or decreased where needed.

The method may further comprise repeating the applying step (b) and the reversing step for at least one time. Where the applying step (b) and the reversing step are repeated for more than one time, they may be repeated in an alternating sequence.

Advantageously, the thermal material has a consistent performance after the repeating step. Therefore, the thermal material may maintain its low response time and high performance when changing the article's apparent temperature.

In the coating step (a), the article may have a temperature that is different from room temperature and is not particularly limited. As an example, the article may be a glassware, an electric appliance, a vehicle or a mammal.

In the coating step (a), the surface of the article is not particularly limited. The thermal material may be coated onto a top surface (where present), a bottom surface (where present), a side surface (where present) or combinations thereof, of the article. The thermal material may alternatively be coated onto an entire surface of the article. Therefore, the article may be fully enclosed within the thermal material.

In the applying step (b), the bias voltage may be suitably selected based on the thickness of the porous membrane of the thermal material. As an example, the bias voltage may start from 1 V and increase by a step of 0.2 V until a desired response is achieved. As an example, where the thickness of the porous membrane is about 10 μm to about 100 μm, the bias voltage may be 3 V.

Where anions of the ionic liquid are driven to the film of reduced graphene oxide by the bias voltage, the film of reduced graphene oxide may be intercalated and doped by the anions. The film of reduced graphene oxide may then have a higher Fermi level (E_{F}) and an increased carrier density. Therefore, the film of reduced graphene oxide may have a greatly suppressed optical absorption and emissivity due to Pauli exclusion principle. Therefore, the method may reduce the article's apparent temperature.

Therefore, there is provided a method of reducing an article's apparent temperature, comprising the steps of:

(a) coating a surface of the article with a thermal material, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane;
(b) applying a bias voltage between the electrode of the thermal material and the film of reduced graphene oxide of the thermal material to drive anions of the ionic liquid to the film of reduced graphene oxide.

Exemplary, non-limiting embodiments of a device will now be disclosed.

The device may comprise:

(a) an article;
(b) a thermal material coated on a surface of the article, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane; and
(c) a power supply connected to the thermal material.

The article may have a temperature that is different from room temperature and is not particularly limited. As an example, the article may be a glassware, an electric appliance, a vehicle or a mammal.

The surface of the article is not particularly limited. The thermal material may be coated onto a top surface (where present), a bottom surface (where present), a side surface (where present) or combinations thereof, of the article. The thermal material may alternatively be coated onto an entire surface of the article. Therefore, the article may be fully enclosed within the thermal material.

The power supply may apply a bias voltage between the electrode of the thermal material and the film of reduced graphene oxide of the thermal material to drive anions of the ionic liquid to the film of reduced graphene oxide. The power supply may provide a direct current and is not particularly limited. As an example, the power supply may be a battery.

The article, the thermal material and the power supply may be integral parts of the device. Therefore, where the device is moved, the article, the thermal material and the power supply may be moved together.

The thermal material may be additionally coated on a surface of the power supply. Therefore, the device may be partially or fully enclosed within the thermal material.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1A shows an embodiment of the thermal material comprising a film of reduced graphene oxide, a porous asymmetric polyethersulfone membrane and a back gold electrode.

FIG. 1B is a schematic illustration of working principles of the thermal material.

FIG. 1C is a schematic illustration of band structure of the film of reduced graphene oxide as described herein when doped with anions.

FIG. 1D is a photograph of an embodiment of the thermal material where flexible materials are used.

FIG. 1E and FIG. 1F are thermal camera images of a beaker filled with boiling water, wherein the beaker is wrapped by the thermal material. In FIG. 1E, no bias voltage is applied on the thermal material, while in FIG. 1F, a bias voltage of 3 V is applied between the electrode and the film of reduced graphene oxide of the thermal material.

FIG. 2A is an atomic force microscope (AFM) height sensor image of graphene oxide flakes (taken on a SiO₂/Si substrate) used in the preparation of the film of reduced graphene oxide.

FIG. 2B shows a corresponding AFM line scan plot of the graphene oxide flakes as shown in FIG. 2A. The graphene oxide flakes had a low height, thus demonstrating that they are single-layered.

FIG. 2C shows X-ray diffraction (XRD) spectra of a film of graphene oxide (that was prepared from the graphene oxide flakes as described above) and a film of reduced graphene oxide (that was prepared from the film of graphene oxide as described above).

FIG. 2D shows Raman spectra of the film of graphene oxide and the film of reduced graphene oxide as described above.

FIG. 2E is a scanning electron microscope (SEM) image of the film of reduced graphene oxide, showing the film's morphology.

FIG. 2F is a cross-sectional SEM image of a combination of the film of reduced graphene oxide and a porous polyethersulfone membrane. The film of reduced graphene oxide has a thickness of about 300 nm as shown in FIG. 2F.

FIG. 3A shows reflectance spectra of the thermal material under varying bias voltages. The reflectance of the thermal material increased with increasing bias voltages.

FIG. 3B shows a variation of emissivity of the thermal material under varying bias voltages.

FIG. 3C shows calculated apparent temperatures of the thermal material with varying emissivities ranged from 0.2 to 1, at a background temperature of 20° C.

FIG. 4A shows thermal camera images (taken at 8 to 13 μm) of a beaker filled with boiling water, wherein the beaker is wrapped by the thermal material. The beaker has a decreasing apparent temperature when a bias voltage of 3 V is applied on the thermal material. The beaker's apparent temperature increases back when the bias voltage is reversed.

FIG. 4B shows the thermal material's response time when the bias voltage is applied.

FIG. 4C shows a cycling test of the thermal material where a periodic voltage is applied (−3 to 3 V), highlighting the thermal material's robustness.

### DETAILED DESCRIPTION

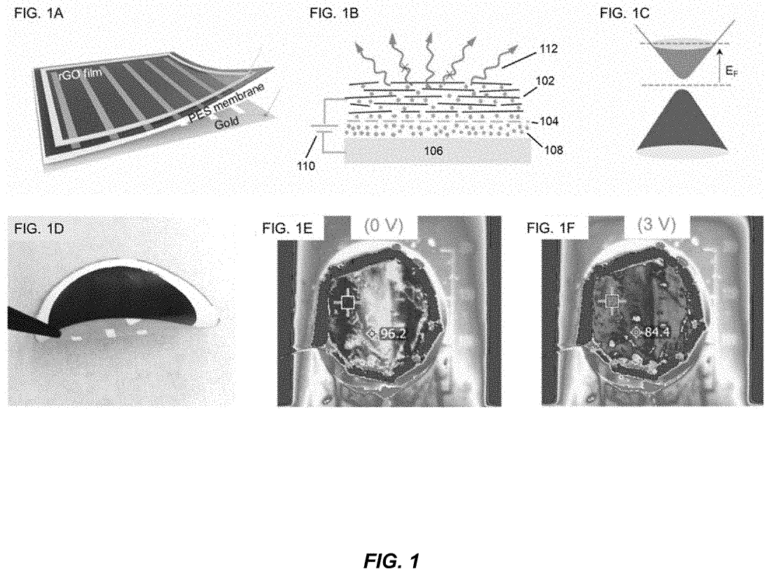

Referring to FIG. 1B, there is provided a schematic illustration of working principles of the thermal material.

The thermal material comprises a film of reduced graphene oxide (102), a porous membrane (104), an electrode (106) and an ionic liquid (108), wherein the porous membrane is sandwiched between the film of reduced graphene oxide and the electrode. The ionic liquid (108) comprises cations and anions and is initially disposed within pores of the porous membrane (104).

Where a power supply (110) is connected to the thermal material to apply a bias voltage between the electrode (106) and the film of reduced graphene oxide (102), the anions of the ionic liquid (108) may be driven towards the film of reduced graphene oxide (102), while the cations of the ionic liquid (108) may be driven towards the electrode (106). The reduced graphene oxide may be intercalated by the anions, thus leading to a lower infrared radiation (112) of the thermal material.

### EXAMPLES

Non-limiting examples of the invention and a comparative example will be further described in greater detail by reference to specific Examples, which should not be construed as in any way limiting the scope of the invention.

### Example 1—Synthesis of Thermal Material

50 mL of diluted graphene oxide (GO, flakes with a size of 1000 to 10000 nm, purchased from Sigma Aldrich, Singapore) dispersion (10 mg/L) was self-assembled onto porous polyethersulfone (PES) having a pore size of 30 nm (purchased from Sterlitech of Auburn, Wash., the United States) under vacuum. A graphene oxide layered material with an interlayer distance from 6.4 to 8.8 Å depending on the graphene oxide's degree of oxidation.

The graphene oxide layered material was then reduced by an aqueous solution of ascorbic acid (30 mg/mL, purchased from Sigma Aldrich, Singapore) by immersion of the material in the solution for 24 hours. It was observed that the material's colour changed from light yellow to dark. In addition, the interlayer distance was reduced to 3.9 Å. Thus, it was shown that a layered composite material of reduced graphene oxide (rGO) was formed on the porous PES material. The layered composite rGO/PES material was then dried overnight at room temperature in a dry cabinet.

A back gold mesh was subsequently deposited on the bottom of the rGO/PES material to form a bottom electrode by atomic layer deposition using a mask. The rGO and the back gold then formed top and bottom electrodes, respectively, while the backside gold mesh also served as an obstruct layer to block transmission of background infrared (IR) radiation.

Eventually, an ionic liquid 1-Butyl-3-methylimidazolium hexafluorophosphate (BMIMPF₆, 97%, purchased from Merck, Singapore) was injected into the porous PES through capillary action by soaking the material in the ionic liquid for 2 hours.

Referring to FIG. 1A, the thermal material may comprise a film of reduced graphene oxide, a porous polyethersulfone membrane and a back gold mesh. The film of reduced graphene oxide may serve as a top electrode while the back gold mesh may serve as a bottom electrode. Therefore, the thermal material may be adapted to be connected to a power supply.

### Example 2—Characterization of Thermal Material

Referring to FIG. 1D, a photograph was taken for the fabricated active thermal material, which was flexible and light, and could be used as a cladding for target objects.

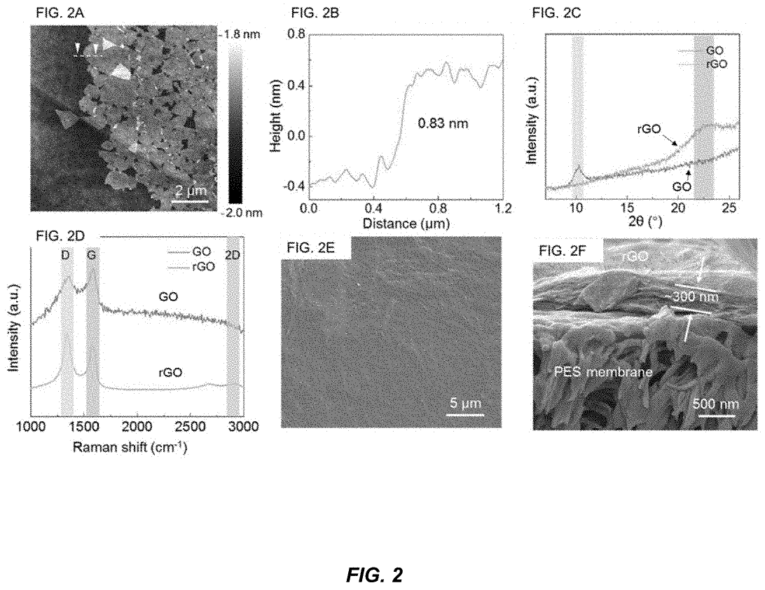

Atomic Force Microscope (AFM, Bruker Dimension Icon) images manifested that the GO flakes used could be homogenously suspended onto SiO₂/Si substrate with a uniform contrast. The lateral size of GO ranged from 1 to 2 μm (FIG. 2A). Moreover, the GO's corresponding height profile demonstrated that it was single-layered with a thickness of about 0.8 nm (FIG. 2B). The rGO film was obtained by directly filtering GO dispersion onto asymmetric polyethersulfone filtration membrane with pore size of 30 nm, followed by ascorbic acid reduction. The XRD, Raman (WITEC ALPHA300R; 532 nm laser excitation, 100× object lens) and X-ray photoelectron spectroscopy (XPS, Kratos Analytical Axis-Ultra spectrometer using a monochromatic Al Kα X-ray source) results confirmed a successful reduction of GO by ascorbic acid. As shown in FIG. 2C, the typical 2θ value of GO was about 10.25° (d-spacing was about 8.60 Å) and the characteristic peak of rGO was dramatically shifted to higher 2θ angles (22.8°, corresponding interlayer spacing was approximately 3.9 Å) due to elimination of epoxy and hydroxyl groups from the GO during the reduction process, reducing the interlayer distance.

FIG. 2D showed the Raman spectra of rGO before and after reduction. It was observed that the G-band (around 1588 cm⁻¹) became obvious because of recovery of the hexagonal structure of C atoms. The intensity of the 2D (2686 cm⁻¹) band also increased, indicating a regraphitization of rGO during the reduction process. However, the D-band's intensity was still higher than that of the G-band, because the gentle reduction process could only partially remove defects and disorders in the rGO that had been formed by oxidation of graphite.

In addition, the C_{1S} XPS spectra also confirmed the successful reduction of GO as indicated by decreases of C—O and O—C═O groups. As shown in the SEM image (Zeiss Sigma 300) of FIG. 2E, the surface morphology of synthesized rGO film was pretty smooth, indicating that transverse and interlayer contraction occurred during the reduction process. The cross-section SEM images manifested that the rGO film was firmly adhered to the PES filter membrane with a thickness of about 300 nm (see FIG. 2F). Further, no obvious gap was observed between the rGO film and the PES membrane.

### Example 3—Doping Effect of Thermal Material

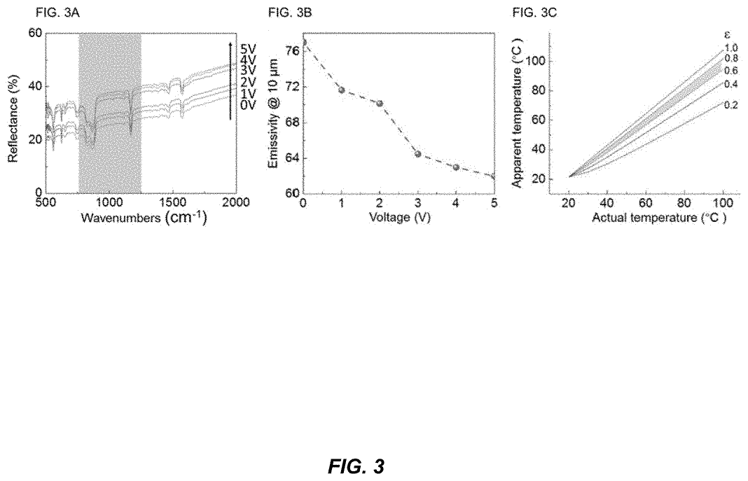

To evidence doping effect of the rGO by intercalation of ions, variation of the thermal material's optical response was measured by a Fourier transform infrared spectrometer (FTIR) under different bias voltages. As shown in FIG. 3A, the thermal material's optical reflectivity increased significantly with an increase in bias voltage over the visible and the full mid-infrared range, and the reflectance was increased by a factor of 1.6 at a bias voltage of 5 V. The suppressed infrared emissivity due to Pauli blocking and the enhanced Drude optical conductance led to increases of the infrared reflectance. However, the electrochemical window of the ionic liquid used limited the maximum value of the applied bias. Moreover, to avoid destruction of the rGO's structure, the applied maximum bias voltage for thermal stealth measurement was set to be 3 V.

Apparent temperatures as detected by a thermal camera followed the Stefan-Boltzmann law, i.e., P=εσT⁴, where P is power of received thermal radiation, ε is emissivity of an object's surface, σ is the Stefan-Boltzmann constant and T is the surface's actual temperature. Therefore, the apparent temperature of the thermal material could be modulated by controlling the emissivity during a reversible intercalation process. The IR emissivity is calculated according to the following equation: Total IR emissivity (%)=100%−Total IR transmittance (%)−Total IR reflectance (%), where the transmittance is negligible in our cases due to the thickness of rGO film and back gold layer. All the measurements were performed at ˜20° C. with the relative humidity of ˜60%. Thus, the emissivity of the thermal material could be modulated from 0.64 (under a bias voltage of 3 V) to 0.77 (under a bias voltage of 0 V, or under no bias voltage) at a spectral sensitivity range of 8 to 13 μm of the thermal camera (see FIG. 3B, FLUKE TiX580 thermal camera). As shown in FIG. 3C, the apparent temperature of the thermal material was calculated from the actual temperature in a range from 0 to 100° C. with the emissivity being in a range between 0 and 1, at a background temperature of 20° C. Apparent temperatures of the shaded areas in FIG. 3C were tuned by the thermal material and measured as shown in the figure.

### Example 4—Performance of Thermal Material

To demonstrate the performance of the thermal material, the thermal material was wrapped around a beaker which was filled with boiling water. At a bias voltage of 0 V, the thermal material had a relatively high thermal emissivity, showing the actual temperature of its surface (see FIG. 1E). A suitable bias voltage of about 3 V was then applied on the thermal material while keeping the water in the beaker boiling. It was observed that the thermal material's emissivity was greatly suppressed, and the detected apparent temperature decreased. Referring to FIG. 1C, under a forward bias voltage, the reduced graphene oxide may be doped via intercalating of the anions of the ionic liquid. This may shift up the E_{F} and lead to a higher carrier density of the reduced graphene oxide. Therefore, the thermal material may have a greatly suppressed optical absorption and emissivity due to Pauli exclusion principle. This effect was not observed in other materials, such as a device where the ionic liquid was sandwiched between two pieces of graphene glass (where graphene was inside).

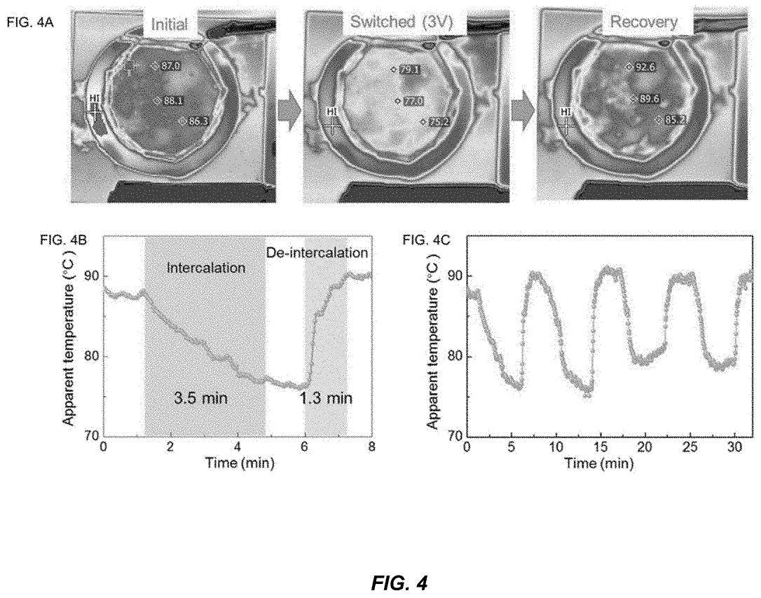

Modulation of the thermal material's apparent temperature was subsequently systematically studied by placing the thermal material on a hot plate at 90° C. Bias voltages of 0 V and 3 V were applied on the thermal material and thermal images were taken. As shown in the left panel of FIG. 4A, the thermal material had a relatively higher apparent temperature revealing its actual temperature, due to its high emissivity at a bias voltage of 0 V. When the bias voltage was increased to 3 V, anions of the ionic liquid would intercalate into rGO interlayers and dope them, suppressing the emissivity and showing a lower apparent temperature. The apparent temperature could reach to 77° C. (see FIG. 4A, middle panel), which was consistent with the calculated results. Moreover, the thermal material could recover to its initial state when a reverse bias voltage was applied (see FIG. 4A, right panel).

Further, the thermal material's temperature response was monitored by plotting apparent temperature vs time (see FIG. 4B). The thermal material had a response time of 3.5 minutes at a bias voltage of 3 V, with a much faster decay time at a reverse voltage of −3 V. The thickness of the original GO flakes was considered as a key factor for the response time. A similar thermal material was fabricated with thicker GO flakes having a thickness of about 1.6 nm (compared to about 0.8 nm as described in Example 2). It was observed that a longer time was needed for anions of the ionic liquid to intercalate, and the performance of the comparative thermal material was also worse.

To demonstrate the thermal material's robustness, it was rigorously tested by cycling many times. It was observed that the values of response time and on/off ratio were almost the same after several cycles (see FIG. 4C). Moreover, no remarkable change was observed in the thermal material's Raman spectra after cycling, manifesting its high stability. Therefore, the thermal material could be effectively used for infrared stealth, owing to its remarkable on/off state, fast response, high durability and low threshold bias voltage.

### Summary of Examples

In conclusion, a thermal material was developed based on rGO that has a low cost. The thermal material's E_{F} may be tuned via intercalation of anions and the corresponding doping effect. The thermal material's emissivity may be modulated from 0.77 down to 0.6 at a bias voltage of 3 V with a fast response and a high durability. A hot object coated with the thermal material may be disguised as a cold one in a thermal camera or a thermal imager, thus achieving an active infrared stealth. Moreover, the thermal material had a simple geometry, which allowed for industrial-scale production for thermal management.

### INDUSTRIAL APPLICABILITY

The thermal material may be used in a variety of applications such as thermal camouflage devices, adaptive IR optics and adaptive heat shields for satellites.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A thermal material comprising:
(a) an electrode;
(b) a film of reduced graphene oxide;
(c) a porous membrane that is sandwiched between the electrode and the film of reduced graphene oxide; and
(d) an ionic liquid that is disposed within pores of the porous membrane.

2. The thermal material of claim 1, wherein the electrode comprises gold, copper, silver, titanium, platinum, tungsten, or combinations thereof.

3. The thermal material of claim 1, wherein the electrode has a thickness in a range of 10 nm to 2000 nm.

4. The thermal material of claim 1, wherein the film of reduced graphene oxide comprises a plurality of single-layered reduced graphene oxide.

5. The thermal material of claim 1, wherein the film of reduced graphene oxide has a thickness in a range of 100 nm to 2000 nm.

6. The thermal material of claim 1, wherein the porous membrane comprises polyethersulfone.

7. The thermal material of claim 1, wherein the porous membrane has a pore size in a range of 10 nm to 1000 nm.

8. The thermal material of claim 1, wherein the porous membrane has a thickness of at least 10 μm.

9. The thermal material of claim 1, wherein the ionic liquid is 1-butyl-3-methylimidazolium hexafluorophosphate.

10. The thermal material of claim 1, wherein the electrode and the porous membrane are flexible.

11. A method of preparing a thermal material, the method comprising:
(a) disposing a film of reduced graphene oxide on a first side of a porous membrane;
(b) adding an electrode on a second side of the porous membrane, the second side being opposite to the first side of the porous membrane; and
(c) filling pores of the porous membrane with an ionic liquid.

12. The method of claim 11, wherein the disposing comprises:
filtering a dispersion of graphene oxide through the porous membrane to form a film of graphene oxide on the porous membrane; and
reducing the film of graphene oxide to form a film of reduced graphene oxide.

13. The method of claim 11, wherein the film of reduced graphene oxide comprises a plurality of single-layered graphene oxide.

14. The method of claim 11, wherein the filling is undertaken by exposing the porous membrane to the ionic liquid.

15. A method of changing an apparent temperature of an article, the method comprising:
(a) coating a surface of the article with a thermal material, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane; and
(b) applying a bias voltage between the electrode of the thermal material and the film of reduced graphene oxide of the thermal material to drive anions of the ionic liquid to the film of reduced graphene oxide.

16. The method of claim 15, wherein the bias voltage is 3 V.

17. The method of claim 15, further comprising reversing the bias voltage to drive anions of the ionic liquid to the electrode.

18. A device comprising:
(a) an article;
(b) a thermal material coated on a surface of the article, the thermal material comprising: (i) an electrode; (ii) a film of reduced graphene oxide; (iii) a porous membrane that is sandwiched between the electrode and the film of reduced graphene oxide; and (iv) an ionic liquid that is disposed within pores of the porous membrane; and
(c) a power supply connected to the thermal material.

19. The device of claim 18, wherein the article, the thermal material and the power supply are integral parts of the device.

20. The device of claim 18, wherein the power supply applies a bias voltage between the electrode of the thermal material and the film of reduced graphene oxide of the thermal material to drive anions of the ionic liquid to the film of reduced graphene oxide.
